(19) United States
(12) Patent Application Publication
(10) Pub. No.: US 2025/0105081 A1
(43) Pub. Date: Mar. 27, 2025

(54) SEMICONDUCTOR DEVICE AND POWER CONTROL UNIT

(71) Applicant: DENSO CORPORATION, Kariya-city (JP)

(72) Inventors: Keita FUKUTANI, Kariya-city (JP); Masanori MIYATA, Kariya-city (JP)

(21) Appl. No.: 18/894,482

(22) Filed: Sep. 24, 2024

(30) Foreign Application Priority Data
Sep. 26, 2023 (JP) 2023-163549

(51) Int. Cl. H01L 23/34; G01K 3/00; H01L 23/00; H01L 23/31; H01L 23/473

(52) U.S. Cl. CPC H01L 23/34; G01K 3/005; H01L 23/3107; H01L 23/473; H01L 24/32; H01L 24/48; H01L 24/73; H01L 2224/32245; H01L 2224/48175; H01L 2224/73265; H01L 2924/10272; H01L 2924/13091

(57) ABSTRACT

A semiconductor device includes: a semiconductor substrate having an active region and an outer peripheral region in which a voltage withstanding structure is formed to surround the active region; a temperature sensor configured to detect a temperature of the semiconductor substrate in the outer peripheral region; and a conductive spacer disposed on the active region. The temperature sensor is positioned not to overlap the conductive spacer in the thickness direction. The temperature sensor is positioned closer to a center of the semiconductor substrate in an orthogonal direction perpendicular to the thickness direction than the voltage withstanding structure is.

### CROSS REFERENCE TO RELATED APPLICATION

This application is based on Japanese Patent Application No. 2023-163549 filed on Sep. 26, 2023, the disclosure of which is incorporated herein by reference.

### TECHNICAL FIELD

The present disclosure relates to a semiconductor device and a power control unit.

### BACKGROUND

A semiconductor device includes a semiconductor substrate, a surface electrode, a field plate electrode, and a temperature sensor. The semiconductor substrate has an element portion provided with a functional structure and a peripheral portion provided with a terminal voltage withstanding structure. The surface electrode is provided on the element portion. The field plate electrode is in contact with the surface electrode and is provided on the terminal voltage withstanding structure. The temperature sensor is provided on the field plate electrode. Joule heat generated in the element portion is transferred to the temperature sensor via the surface electrode and the field plate electrode.

### SUMMARY

According to one aspect of the present disclosure, a semiconductor device includes a semiconductor substrate having an active region in which an element is formed, and an outer peripheral region, in which a voltage withstanding structure is formed, surrounding the active region in a plan view. A temperature sensor detects the temperature of the semiconductor substrate in the outer peripheral region. The semiconductor device is electrically connected to a control device configured to detect whether there is an abnormality in a cooling system that cools the semiconductor substrate based on the temperature detected by the temperature sensor. The semiconductor device further includes a conductive spacer disposed in the active region on one surface of the semiconductor substrate. The temperature sensor is disposed so as not to overlap the conductive spacer in the thickness direction, and located closer to a center of the semiconductor substrate in an orthogonal direction perpendicular to the thickness direction than the voltage withstanding structure is.

### BRIEF DESCRIPTION OF DRAWINGS

FIG. 1 is a schematic diagram illustrating a configuration of a vehicle drive system to which a semiconductor device according to a first embodiment is applied.

FIG. 2 is a plan view illustrating the semiconductor device according to the first embodiment.

FIG. 3 is a cross-sectional view of the semiconductor device taken along line Ill-Ill in FIG. 2.

FIG. 4 is a sectional view of a power control unit.

FIG. 5 is a plan view of a semiconductor substrate.

FIG. 6 is a cross-sectional view taken along line VI-VI in FIG. 5.

FIG. 7 is a cross-sectional view taken along line VII-VII in FIG. 5.

FIG. 8 is a flowchart related to abnormality detection in a cooling system.

FIG. 9 is a plan view illustrating a semiconductor substrate according to a second embodiment.

FIG. 10 is a plan view illustrating a semiconductor substrate according to a third embodiment.

FIG. 11 is a plan view illustrating a semiconductor substrate according to a fourth embodiment.

FIG. 12 is a plan view illustrating a semiconductor substrate according to a fifth embodiment.

### DETAILED DESCRIPTION

A semiconductor device includes a semiconductor substrate, a surface electrode, a field plate electrode, and a temperature sensor. The semiconductor substrate has an element portion provided with a functional structure and a peripheral portion provided with a terminal voltage withstanding structure. The surface electrode is provided on the element portion. The field plate electrode is in contact with the surface electrode and is provided on the terminal voltage withstanding structure. The temperature sensor is provided on the field plate electrode. Joule heat generated in the element portion is transferred to the temperature sensor via the surface electrode and the field plate electrode.

When a temperature sensor is placed on the terminal voltage withstanding structure, it is necessary to provide a special structure such as a field plate electrode between the terminal voltage withstanding structure and the temperature sensor to restrict from being affected by the electric field in the surrounding area. However, it was difficult to both arrange the temperature sensor in the peripheral area without providing a special structure and expand the area of the element portion.

The present disclosure provides a semiconductor device and a power control unit that is capable of both arranging a temperature sensor in a peripheral region and expanding an area of an active region without providing a special structure for restricting the influence of an electric field in the peripheral region.

According to one aspect of the present disclosure, a semiconductor device includes: a semiconductor substrate having an active region in which an element is formed, and an outer peripheral region in which a voltage withstanding structure is formed to surround the active region in a plan view of the thickness direction; and a temperature sensor configured to detect a temperature of the semiconductor substrate in the outer peripheral region. The semiconductor device is electrically connected to a control device that detects whether there is an abnormality in a cooling system based on the temperature detected by the temperature sensor, the cooling system cooling the semiconductor substrate. A conductive spacer is disposed in the active region on one surface of the semiconductor substrate. The temperature sensor is positioned not to overlap the conductive spacer in the thickness direction, and the temperature sensor is positioned closer to a center of the semiconductor substrate in an orthogonal direction perpendicular to the thickness direction than the voltage withstanding structure is.

Since the temperature sensor is required to detect not the maximum temperature of the semiconductor substrate but an abnormality in the cooling system, there are few restrictions on the arrangement of the temperature sensor. Since the temperature sensor is provided closer to the center of the semiconductor substrate than the voltage withstanding structure is, there is no need to provide a special structure to restrict the influence of the electric field due to the voltage withstanding structure. Furthermore, since the temperature sensor does not overlap with the conductive spacer in the thickness direction, there is no need to provide a gap to arrange the temperature sensor in the active region. It has become possible to both arrange the temperature sensor in the outer peripheral region without providing a special structure for restricting the influence of the electric field due to the withstand voltage structure, and to expand the area of the active region.

According to another aspect of the present disclosure, a power control unit includes: a semiconductor substrate having an active region in which an element is formed, and an outer peripheral region in which a voltage withstanding structure is formed to surround the active region in a plan view of a thickness direction; a conductive spacer disposed on one side of the semiconductor substrate in the active region; a temperature sensor configured to detect a temperature of the semiconductor substrate in the outer peripheral region; and a control device configured to detect whether there is an abnormality in a cooling system that cools the semiconductor substrate based on a detected temperature detected by the temperature sensor. The temperature sensor is positioned not to overlap the conductive spacer in the thickness direction and the temperature sensor is positioned closer to a center of the semiconductor substrate in an orthogonal direction perpendicular to the thickness direction than the voltage withstanding structure is.

In the power control unit, it has become possible to arrange the temperature sensor in the outer peripheral region, without providing a special structure to restrict the influence of the electric field due to the voltage withstanding structure and to increase the area of the active region.

Hereinafter, embodiments for carrying out the present disclosure are described with reference to the drawings. In each embodiment, parts corresponding to the elements described in the preceding embodiments are denoted by the same reference numerals, and redundant explanation may be omitted. When only a part of a configuration is described in an embodiment, the other preceding embodiments can be applied to the other parts of the configuration.

In addition, not only the combination between portions explicitly described that the combination is possible in each embodiment, but also partial combinations between the embodiments, between the embodiment and the modification, and between the modifications can be made if there is no problem in the combination in particular even when not explicitly described.

### First Embodiment

A semiconductor device 20 of this embodiment is applied, for example, to a power control unit 4 of a mobile object whose driving source is a rotating electric machine. Examples of the mobile object include electric vehicles such as battery electric vehicle (BEV), hybrid vehicle (HEV), and plug-in hybrid vehicle (PHEV), flying vehicles such as electric vertical takeoff and landing aircraft and drone, ships, construction machinery, and agricultural machinery. Hereinafter, the semiconductor device 20 is applied to a vehicle.

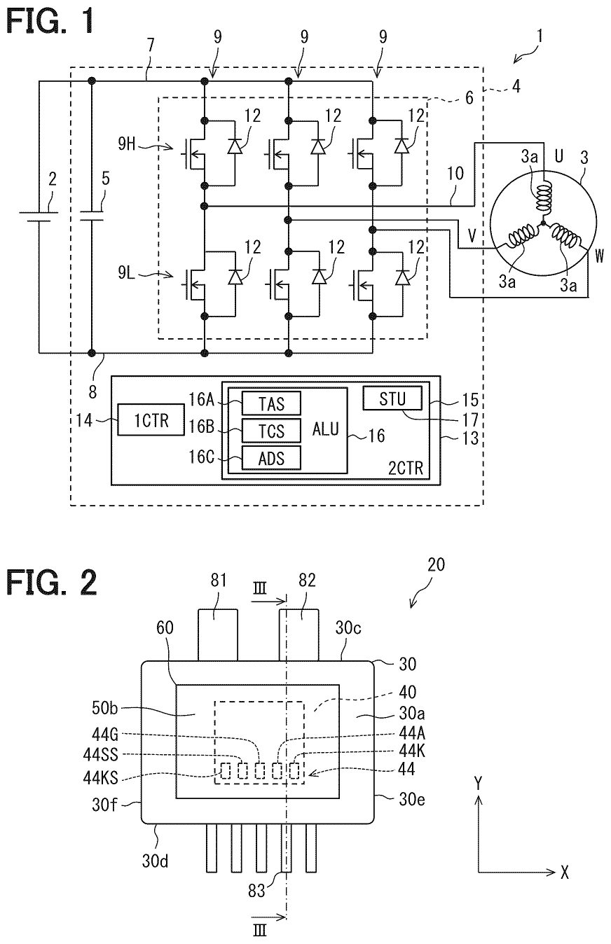

The following describes a schematic configuration of a vehicle drive system 1 with reference to FIG. 1. The vehicle drive system 1 includes a DC power supply 2, a motor generator 3, and a power control unit 4.

The DC power supply 2 is a direct-current voltage source including a chargeable/dischargeable secondary battery. The secondary battery is, e.g., a lithium ion battery or a nickel hydride battery. The motor generator 3 is a three-phase AC type rotating electric machine. The motor generator 3 functions as a vehicle driving power source, that is, an electric motor. The motor generator 3 functions also as a generator during regeneration. The power control unit 4 performs power conversion between the DC power supply 2 and the motor generator 3.

Next, the circuit configuration of the power control unit 4 will be explained. The power control unit 4 includes a power conversion circuit and a control device 13. As shown in FIG. 1, the power control unit 4 includes a smoothing capacitor 5 and an inverter 6 that is a power conversion circuit.

The smoothing capacitor 5 mainly smooths the DC voltage supplied from the DC power supply 2. The smoothing capacitor 5 is connected between a P line 7 which is a power line on a high potential side and an N line 8 which is a power line on a low potential side. The P line 7 is connected to a positive electrode of the DC power supply 2, and the N line 8 is connected to a negative electrode of the DC power supply 2. The positive electrode of the smoothing capacitor 5 is connected to the P line 7 between the DC power supply 2 and the inverter 6. The negative electrode is connected to the N line 8 between the DC power supply 2 and the inverter 6. The smoothing capacitor 5 is connected to the DC power supply 2 in parallel.

The inverter 6 is a DC-AC conversion circuit. The inverter 6 has the semiconductor device 20. The semiconductor device 20 of this embodiment includes a MOSFET as a switching element. The inverter 6 converts the DC voltage into three-phase AC voltage according to switching control by the control device 13 and outputs the AC voltage to the motor generator 3. Thereby, the motor generator 3 is driven to generate a predetermined torque. At the time of regenerative braking of the vehicle, the inverter 6 converts the three-phase AC voltage generated by the motor generator 3 by receiving the rotational force from the wheels into a DC voltage according to the switching control by the control device 13, and outputs the DC voltage to the P line 7. In this way, the inverter 6 performs bidirectional power conversion between the DC power supply 2 and the motor generator 3.

The control device 13 has a control circuit that controls turning on and off of the MOSFET 11. The control circuit controls turning on or off of the plural MOSFETs 11. Accordingly, the power control unit 4 can supply three-phase alternating current with different cycles to the motor generator 3. The control device 13 may include a drive circuit for driving the MOSFET in addition to the control circuit. The drive circuit supplies a drive voltage to the gate of the MOSFET 11 of the corresponding arm based on the drive command of the control circuit.

The control device 13 outputs, for example, a PWM signal as a drive command. The control device 13 includes, for example, a processor and a memory. ECU is an abbreviation of Electronic Control Unit. PWM is an abbreviation for Pulse Width Modulation. The drive circuit drives the corresponding MOSFET 11 by applying a drive current to turn on and off the drive of the corresponding MOSFET 11. The drive circuit may be referred to as a driver.

The control device 13 and the method described in the present disclosure may be realized by a dedicated computer which constitutes a processor programmed to execute one or more functions concretized by computer programs. Alternatively, the device and the method described in the present disclosure may be realized by a dedicated hardware logic circuit. Alternatively, the device and the method according to the present disclosure may be implemented by one or more dedicated computers configured with a combination of a processor that executes a computer program and one or more hardware logic circuits. A computer program may be stored in a computer-readable non-transitory tangible storage medium as an instruction executed by a computer.

The inverter 6 includes upper and lower arm circuits 9 for three phases. The arm circuit 9 may be referred to as leg. Each of the upper and lower arm circuits 9 has an upper arm 9H and a lower arm 9L. The upper arm 9H and the lower arm 9L are connected in series between the P line 7 and the N line 8, with the upper arm 9H on the P line 7 side. A connection point between the upper arm 9H and the lower arm 9L is connected to a winding 3a of a corresponding phase in the motor generator 3 via an output line 10. The inverter 6 has six arms. At least a part of each of the P line 7, the N line 8 and the output line 10 is made of a conductive member such as a bus bar.

In this embodiment, an n-channel MOSFET 11 is used as a switching element constituting each arm. MOSFET is an abbreviation for Metal Oxide Semiconductor Field Effect Transistor. In the upper arm 9H, the drain of the MOSFET 11 is connected to the P line 7. In the lower arm 9L, the source of the MOSFET 11 is connected to the N line 8. The source of the MOSFET 11 in the upper arm 9H and the drain of the MOSFET 11 in the lower arm 9L are connected to each other.

A freewheeling diode 12 is connected in anti-parallel to each of the MOSFETs 11. The diode 12 may be a parasitic diode (body diode) of the MOSFET 11, or may be provided separately from the parasitic diode. The anode of the diode 12 is connected to the source of the corresponding MOSFET 11, and the cathode thereof is connected to the drain.

The switching element is not limited to the MOSFET 11. For example, IGBT may be used. The IGBT is an abbreviation of an insulated gate bipolar transistor. Also in the case of IGBT, a freewheeling diode is connected in anti-parallel.

The power control unit 4 may further include a converter as a power conversion circuit. The converter is a DC-DC converter circuit for converting the DC voltage to a DC voltage with different value. The converter is disposed between the DC power supply 2 and the smoothing capacitor 5. The converter is configured to include, for example, a reactor and the above-described upper and lower arm circuit 9. This configuration can boost and/or suppress voltage. The power control unit 4 may include a filter capacitor to remove power supply noise from the DC power supply 2. The filter capacitor is provided between the DC power supply 2 and the converter.

The power control unit 4 includes a cooler 110 in addition to the configuration described above. The cooler 110 is a device that cools the semiconductor devices 20. The cooler 110 is included in a cooling system 140 having a refrigerant pump 130 to circulate refrigerant to the cooler 110. A power module 120 is configured by the semiconductor devices 20 and the cooler 110. The cooler 110 is connected to a pump or the like and has a layered cooling structure in which the layers are stacked in the Z direction. The cooler 110 includes a supply pipe, a discharge pipe, and plural relay pipes 111. The relay pipes 111 are spanned in a ladder-like manner between the supply pipe and the discharge pipe. The supply pipe and the discharge pipe are connected via the relay pipe 111 in such a manner that the refrigerant can flow therethrough. The semiconductor devices 20 are individually housed between the relay pipes 111 adjacent to each other. The semiconductor device 20 is held between the adjacent relay pipes 111. The semiconductor device 20 is cooled on both sides by the cooler 110.

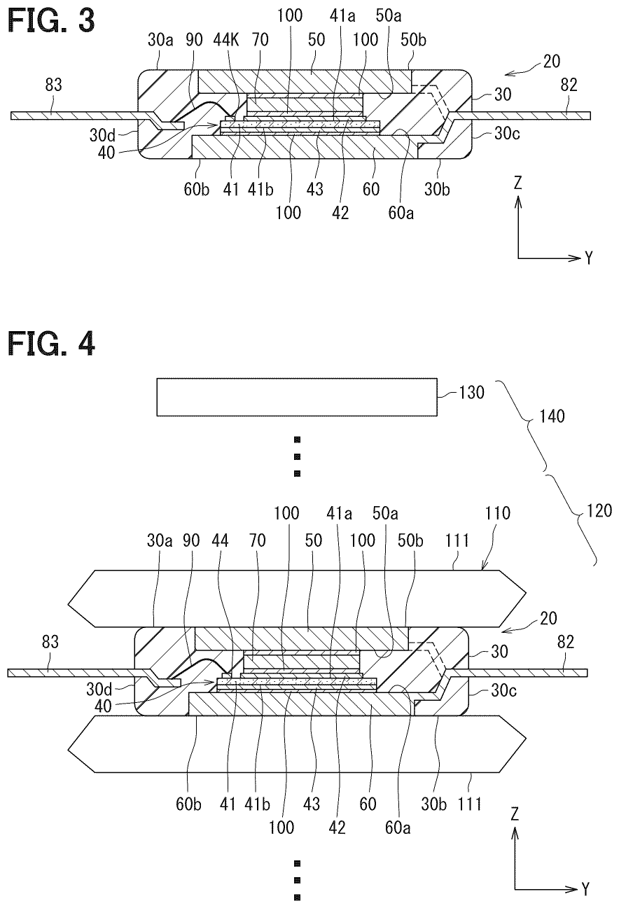

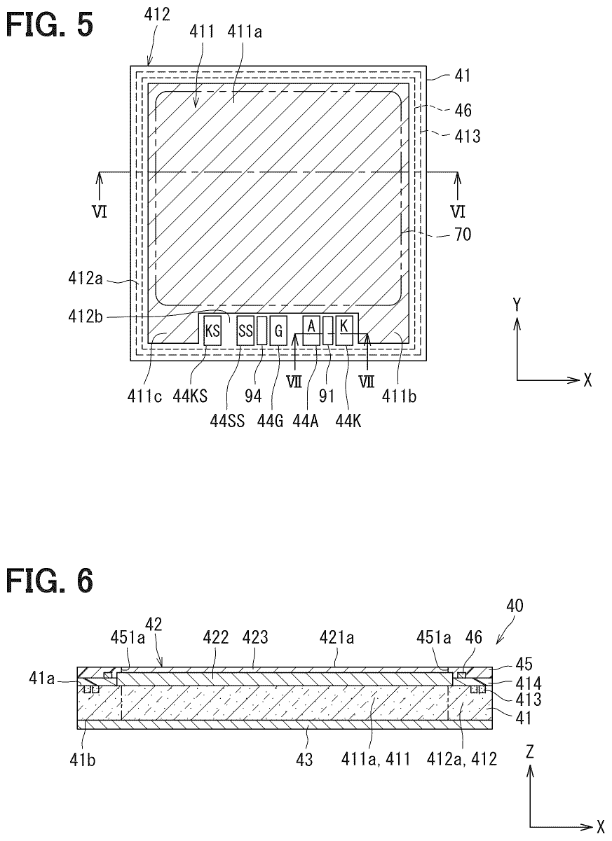

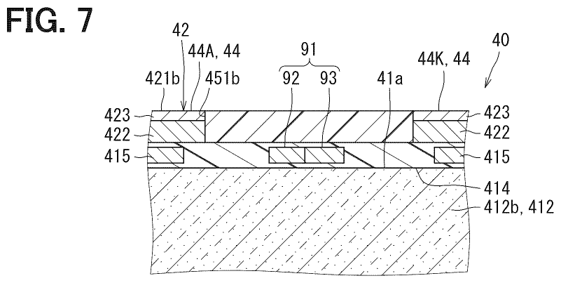

The schematic configuration of the semiconductor device 20 will be described based on FIGS. 2 to 7. FIG. 2 is a plan view showing the semiconductor device 20 according to the first embodiment. FIG. 3 is a cross-sectional view taken along line III-III in FIG. 2. FIG. 4 is a sectional view of the power control unit 4. FIG. 5 is a plan view of the semiconductor substrate 41. FIG. 6 is a cross-sectional view taken along line VI-VI in FIG. 5. FIG. 7 is a cross-sectional view taken along line VII-VII in FIG. 5.

Hereinafter, a thickness direction of the semiconductor element, in other words, the semiconductor substrate is defined as a Z direction. A direction perpendicular to the Z direction is defined as an orthogonal direction. The first direction of the orthogonal directions is the Y direction. A second direction different from the first direction, of the orthogonal direction, is defined as the X direction. Unless otherwise specified, a shape viewed in a plane from the Z direction, that is, a shape along an XY plane defined by the X direction and Y direction is referred to as a planar shape. Further, a planar view in the Z direction may be simply referred to as a plan view.

As shown in FIGS. 2 to 7, the semiconductor device 20 includes a sealing body 30, a semiconductor element 40, wiring members 50 and 60, a conductive spacer 70, and an external connection terminal 80. The semiconductor device 20 further includes a bonding wire 90 and a bonding material 100. The semiconductor device 20 constitutes one of the arms described above. That is, the two semiconductor devices 20 constitute the upper and lower arm circuit 9 for one phase.

The sealing body 30 seals part of other components constituting the semiconductor device 20. The rest of the other components are exposed to the outside of the sealing body 30. The sealing body 30 is made of resin such as epoxy resin. The sealing body 30 is molded by, for example, a transfer molding method using resin as a material. The sealing body 30 is sometimes referred to as a sealing resin body, a mold resin, a resin molded body, or the like. The sealing body 30 may be formed using gel. The gel is placed, for example, in an opposing area of the wiring members 50 and 60.

As shown in FIG. 2 or 3, the sealing body 30 has a substantially rectangular planar shape. The sealing body 30 has one surface 30a and a back surface 30b opposite to each other in the Z direction, as a surface forming an outline. The one surface 30a and the back surface 30b are, for example, substantially flat surfaces. The sealing body 30 has side surfaces 30c, 30d, 30e, 30f continuous with the one surface 30a and the back surface 30b. The main terminal 81, 82 of the external connection terminal 80 protrudes from the side surface 30c. The side surface 30d is opposite to the side surface 30c in the Y direction. The signal terminal 83 projects from the side surface 30d. The external connection terminal 80 does not protrude from the side surface 30e, 30f. The side surface 30e is opposite to the side surface 30f in the X direction.

The semiconductor element 40 includes a semiconductor substrate 41, a source electrode 42, a drain electrode 43, and a pad 44. A gate electrode (not shown) is further formed on the semiconductor substrate 41. The gate electrode has a trench structure, for example. The gate electrode does not have to have a trench structure. The gate electrode may have a planar structure. The semiconductor element 40 is sometimes referred to as a semiconductor chip. The semiconductor substrate 41 is made of a material such as silicon (Si) or a wide bandgap semiconductor having a wider bandgap than silicon, and has a vertical element formed thereon. Examples of the wide bandgap semiconductor include silicon carbide (SiC), gallium nitride (GaN), gallium oxide (Ga₂O₃) and diamond.

The vertical element is configured to allow a main current to flow in the thickness direction of the semiconductor substrate 41. The semiconductor element 40 is arranged so that its thickness direction is substantially parallel to the Z direction. The semiconductor element 40 has main electrodes on both sides in the thickness direction. The semiconductor substrate 41 of this embodiment has the n-channel MOSFET 11 as a vertical element on the semiconductor substrate 41 made of SiC. As shown in FIG. 3, the semiconductor substrate 41 has a source electrode 42 as a main electrode on one surface 41a opposing the wiring member 50, and a drain electrode 43 on a back surface 41b opposite to the one surface 41a.

When the MOSFET 11 is turned on, a current (main current) flows between the main electrodes, that is, between the drain electrode 43 and the source electrode 42. When the diode 12 is a parasitic diode, the source electrode 42 also serves as an anode electrode, and the drain electrode 43 serves as a cathode electrode. The diode 12 may be configured on a separate chip from the MOSFET 11. The drain electrode 43 is the main electrode on the high potential side, and the source electrode 42 is the main electrode on the low potential side. The drain electrode 43 is formed on almost the entire lower surface. The source electrode 42 is formed on a portion of the upper surface.

The pad 44 is an electrode for a signal. The pad 44 is formed on the one surface 41a of the semiconductor substrate 41 in a region different from the region where the source electrode 42 is formed. As an example, as shown in FIG. 5, the semiconductor substrate 41 has five pads 44. Specifically, the semiconductor substrate 41 has a gate pad 44G, a Kelvin source pad 44KS, a cathode potential detection pad 44K of the temperature sensor 91, an anode potential detection pad 44A of the temperature sensor 91, and a current sensing pad 44SS.

The five pads 44 are arranged along the X direction. The five pads 44 are arranged in this order from the side surface 30f to the side surface 30e: the Kelvin source pad 44KS, the current sensing pad 44SS, the gate pad 44G, the anode potential detection pad 44A, and the cathode potential detection pad 44K. Each of the pads 44 is electrically connected to a corresponding signal terminal 83 via a bonding wire 90. The distance between two adjacent pads 44 is set to ensure the insulation of the bonding wire 90. The number and arrangement order of the pads 44 are not limited to these.

The wiring member 50 is electrically connected to the source electrode 42 and provides a wiring function. Similarly, the wiring member 60 is electrically connected to the drain electrode 43 and provides a wiring function. The wiring members 50 and 60 are arranged to sandwich the semiconductor element 40 in the Z direction. The wiring members 50 and 60 are arranged so that at least a portion thereof faces each other in the Z direction. The wiring members 50 and 60 include the semiconductor element 40 in a plan view.

The wiring member 50, 60 provides a heat radiation function of radiating heat generated by the semiconductor element 40. The wiring member 50, 60 is sometimes referred to as radiating board, heat sink, or the like. The wiring member 50, 60 of this embodiment is metal plate made of a metal with good conductivity such as Cu or Cu alloy. The metal plate is provided, for example, as part of a lead frame. Instead of the metal plate, a substrate may be used in which metal bodies are arranged on both sides of an insulating base material. The wiring member 50, 60 may include a plating film of Ni, Au, or the like on the metal surface.

The wiring member 50 has an opposing surface 50a opposing the semiconductor element 40, and a back surface 50b opposite to the opposing surface 50a. Similarly, the wiring member 60 has an opposing surface 60a and a back surface 60b. The wiring member 50, 60 has, for example, a substantially rectangular planar shape. The back surface 50b, 60b of the wiring member 50, 60 is exposed from the sealing body 30. The back surface 50b, 60b is sometimes referred to as heat radiation surface, exposed surface, and the like. The back surface 50b of the wiring member 50 is substantially flush with the one surface 30a of the sealing body 30. The back surface 60b of the wiring member 60 is substantially flush with the back surface 30b of the sealing body 30.

The conductive spacer 70 is interposed between the semiconductor element 40 and the wiring member 50. The conductive spacer 70 provides a spacer function to ensure a predetermined distance between the semiconductor element 40 and the wiring member 50. The conductive spacer 70 ensures the loop height of the bonding wire 90 when the corresponding signal terminal 83 is connected to the pad 44 of the semiconductor element 40 with the bonding wire 90. The conductive spacer 70 is located in the middle of the electrical and thermal conduction path between the source electrode 42 of the semiconductor element 40 and the wiring member 50, and provides a wiring function and a heat dissipation function.

The conductive spacer 70 includes a metal material with good electrical conductivity and thermal conductivity, such as Cu (copper). The conductive spacer 70 may include a plating film on a face thereof. The conductive spacer 70 is sometimes called a terminal, a metal block, or the like. The semiconductor device 20 includes the conductive spacers 70 whose number is identical to the number of the semiconductor elements 40. The conductive spacers 70 are individually connected to the semiconductor elements 40. The conductive spacer 70 has, for example, a columnar body.

The external connection terminal 80 electrically connects the semiconductor device 20 to an external device. The external connection terminal 80 is formed using a metal material having good conductivity such as copper. The external connection terminal 80 is, for example, a plate member. The external connection terminal 80 may be referred to as a lead. The external connection terminal 80 includes the main terminals 81 and 82 and the signal terminal 83. The main terminal 81, 82 of the external connection terminal 80 is electrically connected to the main electrode of the semiconductor element 40.

The main terminal 81 is electrically connected to the source electrode 42. The main terminal 81 is also referred to as a source terminal. The main terminal 81 is connected to the source electrode 42 via the wiring member 50. The main terminal 81 is connected to one end of the wiring member 50 in the Y direction. The thickness of the main terminal 81 is thinner than the wiring member 50. The main terminal 81 is continuous with the wiring member 50, for example, so as to be substantially flush with the opposing surface 50a. The main terminal 81 may be continuously and integrally provided with the wiring member 50, or may be provided as a separate member and connected by joining.

The main terminal 81 of this embodiment is provided integrally with the wiring member 50 as a part of the lead frame. The main terminal 81 extends from the wiring member 50 in the Y direction and projects outward from the side surface 30c of the sealing body 30. The main terminal 81 has a bent part in the middle of the portion covered by the sealing body 30, and protrudes from near the center in the Z direction on the side surface 30c.

The main terminal 82 is electrically connected to the drain electrode 43. The main terminal 82 is also referred to as a drain terminal. The main terminal 82 is connected to the drain electrode 43 via the wiring member 60. The main terminal 82 is connected to one end of the wiring member 60 in the Y direction. The thickness of the main terminal 82 is thinner than that of the wiring member 60. The main terminal 82 is connected to the wiring member 60, for example, so as to be substantially flush with the opposing surface 60a. The main terminal 82 may be continuously and integrally provided with the wiring member 60, or may be provided as a separate member and connected by joining.

The main terminal 82 of this embodiment is provided integrally with the wiring member 60 as a part of a lead frame separate from the main terminal 81. The main terminal 82 extends from the wiring member 60 in the Y direction and projects outward from the side surface 30c, the same as the main terminal 81. The main terminal 82 has a bent part in the middle of the portion covered by the sealing body 30, and protrudes from near the center in the Z direction on the side surface 30c. The two main terminals 81 and 82 are arranged side by side in the X direction so that their side surfaces oppose to each other.

The signal terminal 83 is electrically connected to the corresponding pad 44 of the semiconductor element 40. The signal terminal 83 is electrically connected to the pad 44 via the bonding wire 90. The signal terminal 83 extends in the Y direction and projects outward from the side surface 30d of the sealing body 30. The semiconductor device 20 of this embodiment includes five signal terminals 83 corresponding to the pads 44. The five signal terminals 83 are arranged in the X direction. The signal terminal 83 is configured, for example, by a common lead frame with the wiring member 60 and the main terminal 82. The signal terminals 83 are electrically isolated from each other by cutting tie bars (not shown).

The bonding material 100 is interposed between the elements constituting the semiconductor device 20 and bonds the elements together. The bonding material 100 is, for example, solder. The semiconductor device 20 includes the plural bonding materials 100. One of the bonding materials 100 is interposed between the source electrode 42 and the conductive spacer 70 to bond the source electrode 42 and the conductive spacer 70 together. Another one of the bonding materials 100 is interposed between the conductive spacer 70 and the wiring member 50 to join the conductive spacer 70 and the wiring member 50. Another one of the bonding materials 100 is interposed between the drain electrode 43 of the semiconductor element 40 and the wiring member 60 to bond the drain electrode 43 and the wiring member 60 together.

The semiconductor element 40 is arranged between the wiring member 50 and the wiring member 60 in the Z direction. The semiconductor element 40 is sandwiched between the wiring members 50 and 60 arranged opposite to each other. Thereby, the heat of the semiconductor element 40 can be dissipated to both sides in the Z direction. The semiconductor device 20 has a double-sided heat dissipation structure. The back surface 50b of the wiring member 50 is substantially flush with the one surface 30a of the sealing body 30. The back surface 60b of the wiring member 60 is substantially flush with the back surface 30b of the sealing body 30. Since the back surfaces 50b, 60b are exposed surfaces, it is possible to enhance the heat dissipation.

The semiconductor substrate 41 has a substantially rectangular shape in a plan view. As shown in FIG. 5, the semiconductor substrate 41 has an active region 411 and an outer peripheral region 412. The vertical elements are formed in the active region 411. The active region 411 is sometimes referred to as a main region, a cell region, or the like. In order to distinguish between the active region 411 and the outer peripheral region 412 in the drawings, the active region 411 is hatched in the plan view.

The active region 411 includes a central active region 411a, a right-most active region 411b, and a left-most active region 411c. The central active region 411a has a substantially rectangular shape in a plan view. The central active region 411a is adjacent to the pad 44 in the Y direction. The central active region 411a includes the conductive spacer 70 in a plan view. In FIG. 5, the conductive spacer 70 is indicated by a two-dot chain line. The central active region 411a may be referred to as a main region. The right-most active region 411b and the left-most active region 411c may be referred to as extension region.

The right-most active region 411b is continuous with the right end of the central active region 411a adjacent to the pad 44. The right end is adjacent to the side surface 30e. The left-most active region 411c is connected to the left end of the central active region 411a adjacent to the pad 44. The left end is adjacent to the side surface 30f. The active region 411 has a substantially U-shape in a plan view. The active region 411 is provided with plural cells (unit structures). A MOSFET is configured by connecting the cells in parallel to each other.

The outer peripheral region 412 surrounds the active region 411 in a plan view. The two-dot chain line shown in FIG. 6 indicates the boundary between the active region 411 and the outer peripheral region 412. The outer peripheral region 412 includes a first outer peripheral region 412a and a second outer peripheral region 412b. The first outer peripheral region 412a corresponds to an annular region surrounding the active region 411 along the outer periphery of the semiconductor substrate 41. The second outer peripheral region 412b of the outer peripheral region 412 is adjacent to the central active region 411a, the right-most active region 411b, and the left-most active region 411c. The second outer peripheral region 412b can also be said to be a region surrounded by the central active region 411a, the right-most active region 411b, and the left-most active region 411c.

A voltage withstanding structure 413 is formed in the first outer peripheral region 412a. In this embodiment, a guard ring is formed as the voltage withstanding structure 413. The voltage withstanding structure 413 is configured in an annular shape along the outer periphery of the semiconductor substrate 41. Further, an insulating film 414 is provided on the one surface 41a of the semiconductor substrate 41 corresponding to the outer peripheral region 412. Although not shown, a gate insulating film is formed on the wall surface of the trench. A gate electrode is formed on the surface of the gate insulating film so as to fill the trench. Further, although not shown, the insulating film 414 is provided to cover the gate electrode.

The semiconductor element 40 further includes a protective film 45 disposed on the insulating film 414. The protective film 45 is provided on the insulating film 414 so as to cover the peripheral edge of the source electrode 42. As a material of the protective film 45, for example, polyimide, a silicon nitride film, or the like can be adopted.

The protective film 45 has a first opening 451a and a second opening 451b. The first opening 451a defines a bonding region between the source electrode 42 and the bonding material 100. The first opening 451a and the second opening 451b are through holes that penetrate the protective film 45 in the Z direction. The first opening 451a is provided so as to overlap the source electrode 42 in a plan view. The first opening 451a substantially coincides with the active region 411 in a plan view. The second opening 451b is provided so as to overlap the pad 44 in a plan view. Five second openings 451b are provided corresponding to the pads. The second opening 451b will be explained later.

The source electrode 42 has a first exposed portion 421a exposed from the first opening 451a of the protective film 45 to provide a bonding region with the conductive spacer 70. The first exposed portion 421a is arranged on the active region 411 of the semiconductor substrate 41. The source electrode 42 has a multilayer structure. The source electrode 42 has a base electrode 422 and a connection electrode 423.

The base electrode 422 is a metal layer disposed adjacent to the semiconductor substrate 41 in the source electrode 42 having a multilayer structure. The base electrode 422 is formed using, for example, a material whose main component is Al (aluminum). The base electrode 422 of this embodiment is formed using an Al alloy such as AlSi or AlSiCu. The base electrode 422 is sometimes referred to as a wiring electrode, a base layer, a first metal layer, or the like.

The base electrode 422 includes the active region 411 and extends above the outer peripheral region 412 in a plan view. The base electrode 422 is connected to the source and anode of the vertical element. The base electrode 422 is continuous with the insulating film 414 in the orthogonal direction. The protective film 45 is arranged on the insulating film 414 so as to cover the peripheral edge of the base electrode 422.

The connection electrode 423 is stacked on the base electrode 422. The connection electrode 423 is also referred to as an overlying electrode, upper electrode, upper layer electrode, upper layer, or second metal layer. The connection electrode 423 includes at least metal for solder connection with the conductive spacer 70. The connection electrode 423 may contain a nonmetal as well as a metal. The connection electrode 423 is stacked on the base electrode 422 in the first opening 451a of the protective film 45. The outer peripheral end of the connection electrode 423 is in contact with the inner peripheral surface of the protective film 45 that defines the first opening 451a. The first exposed portion 421a is provided on the outer surface of the connection electrode 423.

The pad 44 has a similar configuration to the source electrode 42. The base electrode 422 of the pad 44 is arranged adjacent to the semiconductor substrate 41 in the source electrode 42 having a multilayer structure. The connection electrode 423 of the pad 44 is stacked on the base electrode 422 of the pad 44. The source electrode 42 of the pad 44 has a second exposed portion 421b exposed from the second opening 451b of the protective film 45 to provide a bonding region between the source electrode 42 and the bonding wire 90. The outer peripheral end of the connection electrode 423 of the pad 44 is in contact with the inner peripheral surface of the protective film 45 that defines the second opening 451b. The second exposed portion 421b is provided on the outer surface of the connection electrode 423 of the pad 44.

The semiconductor element 40 includes a gate wiring 46 as a wiring part. The gate wiring 46 is disposed at a position that does not overlap the source electrode 42 and the pad 44 in a plan view, and is covered with the protective film 45. The gate wiring 46 electrically connects the gate electrode of the MOSFET 11 formed on the semiconductor substrate 41 and the gate pad 44G. The gate wiring 46 is a metal wiring formed using a material whose main component is Al (aluminum), for example. The gate wiring 46 is electrically connected to the gate electrode via a wiring (not shown).

The entire length of the gate wiring 46 of this embodiment is arranged on the first outer peripheral region 412a. The gate wiring 46 is arranged in a ring shape so as to surround the active region 411 and the second outer peripheral region 412b. The voltage withstanding structure 413 is configured in a ring shape along the outer periphery of the semiconductor substrate 41 so as to surround the gate wiring 46. In a plan view, the gate wiring 46 is provided closer to the active region 411 and the second outer peripheral region 412b than the voltage withstanding structure 413 is. In a plan view, the voltage withstanding structure 413 is provided outwardly away from the active region 411 and the second outer peripheral region 412b to an extent that allows the gate wiring 46 to be arranged.

The semiconductor device 20 has a temperature sensor 91. The temperature sensor 91 has a P-type anode region 92 and an N-type cathode region 93. The anode region 92 and the cathode region 93 constitute a PN diode. The anode region 92 and the cathode region 93 are formed by doping polysilicon disposed on semiconductor substrate 41 with impurities. The temperature sensor 91 is provided in an inactive area. The anode region 92 and the cathode region 93 are covered with an insulating film 414. The anode region 92 is electrically connected to the anode potential detection pad 44A, and the cathode region 93 is electrically connected to the cathode potential detection pad 44K via a wiring 415 that is a part of the polysilicon wiring covered with the insulating film 414. The anode potential detection pad 44A and the cathode potential detection pad 44K are electrically connected to the control device 13 via the bonding wire 90 and the signal terminal 83.

The control device 13 applies a voltage that is more positive to the anode region 92 than that to the cathode region 93 and controls to flow a constant current between the anode region 92 and the cathode region 93. When the semiconductor device 20 is in the on mode, the current flows through the active region 411, so Joule heat is generated in the active region 411. As a result, the temperature of the semiconductor substrate 41 increases. Then, the forward voltage of the PN diode of the temperature sensor 91 changes depending on the temperature of the semiconductor substrate 41. The control device 13 measures the forward voltage of the PN diode of the temperature sensor 91 and detects the temperature from the measured value.

It is generally known that in the semiconductor substrate 41, the closer to the center of the active region 411, the higher the temperature is. When the temperature sensor 91 is used to protect the semiconductor substrate 41 from overheating, the temperature sensor 91 is often placed near the center where the temperature is highest. According to this, the temperature sensor 91 can detect the maximum temperature of the semiconductor substrate 41. By detecting the maximum temperature using the temperature sensor 91, it is possible to quickly restrict the semiconductor substrate 41 from overheating.

In this embodiment, the temperature sensor 91 is not provided at the center of the active region 411. In this embodiment, the temperature sensor 91 is provided in the second outer peripheral region 412b. The temperature sensor 91 of this embodiment does not detect the maximum temperature, but rather detects the temperature of the second outer peripheral region 412b. In this embodiment, the temperature sensor 91 is used for the purpose of detecting an abnormality in the cooling system 140. The detection of an abnormality in the cooling system 140 will be explained later.

The arrangement of the temperature sensor 91 will be further explained below. As described above, the conductive spacer 70 is included in the central active region 411a in a plan view. The second outer peripheral region 412b is an area surrounded by the central active region 411a, the right-most active region 411b, and the left-most active region 411c. Further, the second outer peripheral region 412b is annularly surrounded by the first outer peripheral region 412a in which the voltage withstanding structure 413 is provided. According to this, it can be said that the temperature sensor 91 does not overlap the conductive spacer 70 in a plan view, and is provided closer to the center of the semiconductor substrate 41 in the orthogonal direction than the voltage withstanding structure 413 is. More specifically, the temperature sensor 91 is provided in the gap between the anode potential detection pad 44A and the cathode potential detection pad 44K in the second outer peripheral region 412b. The arrangement of the temperature sensor 91 is not limited to this.

As described above, the semiconductor device 20 is cooled by the cooler 110. Since the heat of the semiconductor substrate 41 is radiated to the cooler 110, the temperature of the semiconductor substrate 41 is lower than when the semiconductor device 20 is not cooled by the cooler 110. The temperature sensor 91 detects the actual temperature of the second outer peripheral region 412b in a state where the heat of the semiconductor substrate 41 is radiated to the cooler 110. The actual temperature detected by the temperature sensor 91 may be referred to as a detected temperature.

The temperature sensor 91 is electrically connected to the control device 13. The control device 13 has a first control unit 14 and a second control unit 15. The first control unit 14 includes the drive circuit and the control circuit. The second control unit 15 detects that an abnormality has occurred in the cooling system 140 when the actual temperature of the detection target region on the semiconductor substrate 41 is out of the assumed temperature range described below. The detection target area is, for example, the second outer peripheral region 412b. In this embodiment, the second control unit 15 is applied to a microcomputer. In the drawings, the first control unit 14 is abbreviated as “1CTR”. The second control unit 15 is abbreviated as “2CTR”.

The second control unit 15 includes a calculation unit 16 such as a CPU, a storage unit 17 including a volatile memory such as a RAM, a nonvolatile memory such as a ROM, and an input/output interface (not shown). In the second control unit 15, the calculation unit 16 executes the program stored in the storage unit 17. The calculation unit 16 performs various calculation processes by executing programs. The calculation unit 16 executes predetermined mathematical expressions when performing various calculation processes. Further, the calculation unit 16 performs calculation processing using various signals input to the interface.

The storage unit 17 stores the assumed temperature of the detection target area. The assumed temperature is a predetermined temperature range of the second outer peripheral region 412b, which is assumed to be detected by the temperature sensor 91 when the cooling system 140 is not clogged and the refrigerant flows normally. The calculation unit 16 includes a temperature acquisition unit 16A, a temperature comparison unit 16B, and an abnormality detection unit 16C as functional blocks. The second control unit 15 can detect whether an abnormality has occurred in the cooling system 140 by executing each functional block.

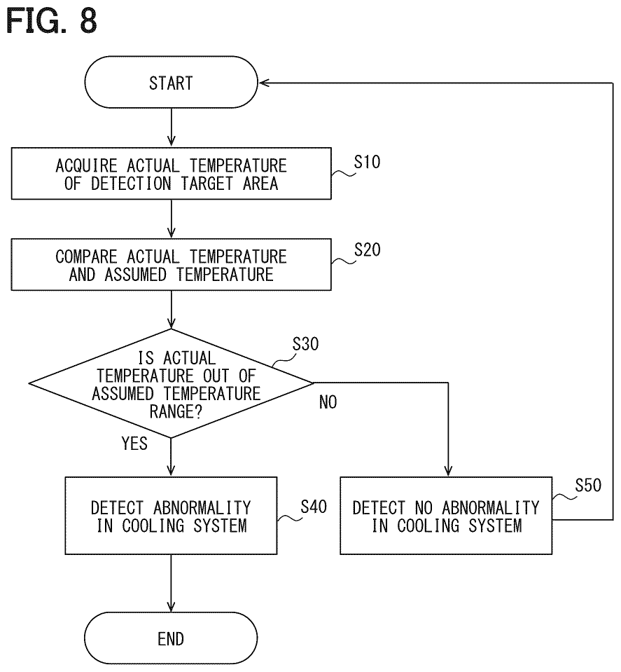

FIG. 8 is a flowchart related to the abnormality detection of the cooler 110 by the second control unit 15. In step S10, the temperature acquisition unit 16A acquires the actual temperature of the detection target area on the semiconductor substrate 41. In step S20, the temperature comparison unit 16B compares the actual temperature of the detection target area and the assumed temperature. If the actual temperature is out of the assumed temperature range in step S30, the abnormality detection unit 16C detects that there is an abnormality in the cooling system 140 in step S40, and the process proceeds to END. After that, the control device 13 performs a protection operation to protect the inverter 6. The protection operation may be performed by the second control unit 15 or may not be performed by the second control unit 15. The protection operation only needs to be performed by the control device 13. The control device 13 includes a protection unit that performs a protection operation for the inverter 6. Further, in step S30, when the actual temperature is within the expected temperature range, the abnormality detection unit 16C detects that there is no abnormality in the cooling system 140 in step S50, and the process returns to START. When the actual temperature is within the assumed temperature range in step S30, the flow is repeated until it is detected that there is an abnormality in the cooling system 140.

Note that in the drawings, the calculation unit 16 is abbreviated as “ALU”. The temperature acquisition unit 16A is abbreviated as “TAS”. The temperature comparison unit 16B is abbreviated as “TCS”. The abnormality detection unit 16C is abbreviated as “ADS”. The storage unit 17 is abbreviated as “STU”.

The semiconductor device 20 further includes a current sensor 94. The current sensor 94 has a function of detecting overcurrent flowing through the vertical element. The current sensor 94 includes a smaller number of unit cells having the same configuration as the vertical element than the number of unit cells of the main semiconductor element 11.

The active region of the current sensor 94 occupies a smaller surface area on the semiconductor substrate 41 than the main vertical element. In the current sensor 94 having a small surface area, leakage current of the gate insulating film due to static electricity generated during the manufacturing process becomes high. Therefore, compared to the main vertical element, the current sensor 94 has lower ESD resistance and is more prone to dielectric breakdown. In this embodiment, as described above, a gap is provided between two adjacent pads 44 with a predetermined distance between them to maintain the insulation properties of the adjacent bonding wires 90. The width of the gap between the two pads 44 is shorter than the length of the pad 44 in the Y direction. The current sensor 94 of this embodiment is provided in the gap between the gate pad 44G and the current sensing pad 44SS in the X direction.

The length of the current sensor 94 in the X direction corresponds to the width of the gap in the X direction. The length of the current sensor 94 in the Y direction corresponds to the length of the pad 44 in the Y direction. The length of the current sensor 94 in the X direction is longer than the length of the current sensor 94 in the Y direction. In this embodiment, the width of the gap between the two pads 44 is defined by design requirements, the surface area of the current sensor 94 is increased by making the length of the current sensor 94 in the Y direction longer than the length of the current sensor 94 in the X direction. According to this, a decrease in ESD tolerance is easily suppressed.

The semiconductor device 20 has the semiconductor substrate 41 and the temperature sensor 91. The semiconductor substrate 41 has the active region 411 and the outer peripheral region 412. The vertical element is formed in the active region 411. The outer peripheral region 412 surrounds the active region 411 in a plan view and has the voltage withstanding structure 413 formed therein. The temperature sensor 91 detects the temperature of the semiconductor substrate 41. The semiconductor device 20 is electrically connected to the control device 13. The control device 13 has a function of detecting whether there is an abnormality in the cooling system 140 that cools the semiconductor substrate 41 based on the detected temperature detected by the temperature sensor 91.

The semiconductor device 20 further includes the source electrode 42, the drain electrode 43, and the conductive spacer 70. The source electrode 42 is disposed in the active region 411 on the one surface 41a of the semiconductor substrate 41 and is electrically connected to the vertical element. The drain electrode 43 is arranged on the back surface and electrically connected to the vertical element. The conductive spacer 70 is provided on the source electrode 42 and connected to the source electrode 42. The temperature sensor 91 is disposed so as not to overlap the conductive spacer 70 in the Z direction and positioned closer to the center of the semiconductor substrate 41 than the voltage withstanding structure 413 is in the orthogonal direction.

When the function of the temperature sensor 91 is to detect the maximum temperature of the semiconductor substrate 41, it is required to be placed near the center of the semiconductor substrate 41 in the orthogonal direction where the temperature is highest. However, in this embodiment, the function of the temperature sensor 91 is to detect an abnormality in the cooling system 140. Therefore, it is not necessary to provide the temperature sensor 91 near the center of the semiconductor substrate 41 in the orthogonal direction. There are fewer restrictions on the arrangement of the temperature sensor 91.

If the temperature sensor 91 is placed on the voltage withstanding structure 413, a special arrangement such as field plate electrode is provided to restrict it from being influenced by the electric field of the voltage withstanding structure 413. However, in this embodiment, the temperature sensor 91 is provided in a region closer to the center of the semiconductor substrate 41 than the outer peripheral region 412 is. Therefore, there is no need to provide a special structure such as a field plate electrode to restrict the influence of the electric field caused by the voltage withstanding structure 413. The concentration of the electric field on the temperature sensor 91 can be suppressed.

Furthermore, when the temperature sensor 91 overlaps the conductive spacer 70 in the Z direction, the active region 411 is reduced by the area of the temperature sensor 91. However, in this embodiment, the temperature sensor 91 does not overlap with the conductive spacer 70 in the Z direction. Therefore, it is possible to suppress the active region 411 from decreasing by the area of the temperature sensor 91. In other words, it is possible to both arrange the temperature sensor 91 in the outer peripheral region 412 and expand the area of the active region 411 without providing a special structure for restricting the influence of the electric field caused by the voltage withstanding structure 413.

The semiconductor device 20 has the plural pads 44 arranged in the outer peripheral region 412. The pads 44 are arranged and separted from the conductive spacer 70 in the Y direction. The pads 44 are arranged with gaps in between in the X direction. The temperature sensor 91 is arranged between two adjacent pads 44. The active region 411 can be expanded to the area adjacent to the pad 44.

The active region 411 has the central active region 411a, the right-most active region 411b, and the left-most active region 411c. The central active region 411a is arranged adjacent to the pads 44 in the Y direction. The right-most active region 411b is continuous with the right end of the central active region 411a adjacent to the pad 44. The left-most active region 411c is continuous with the left end of the right-most active region 411b adjacent to the pad 44. The active region 411 can be expanded into the central active region 411a, the right-most active region 411b, and the left-most active region 411c. The area of the active region 411 can be increased.

The power control unit 4 includes the semiconductor device 20 and the control device 13. The control device 13 detects whether there is an abnormality in the cooling system 140 that cools the semiconductor substrate 41 based on the detected temperature detected by the temperature sensor 91. Similar effects can be achieved in the power control unit 4.

The control device 13 includes the storage unit 17, the temperature acquisition unit 16A, the temperature comparison unit 16B, and the abnormality detection unit 16C. The storage unit 17 stores the assumed temperature having a predetermined temperature range assumed to be detected by the temperature sensor 91 when the refrigerant normally flows through the cooling system 140. The temperature acquisition unit 16A acquires the actual temperature of the semiconductor substrate 41 detected by the temperature sensor 91. The temperature comparison unit 16B compares the actual temperature of the semiconductor substrate 41 and the assumed temperature. The abnormality detection unit 16C detects that there is an abnormality in the cooling system 140 when the actual temperature is out of the assumed temperature range. An abnormality in the cooling system 140 can be detected based on the temperature detected by the temperature sensor 91.

### Second Embodiment

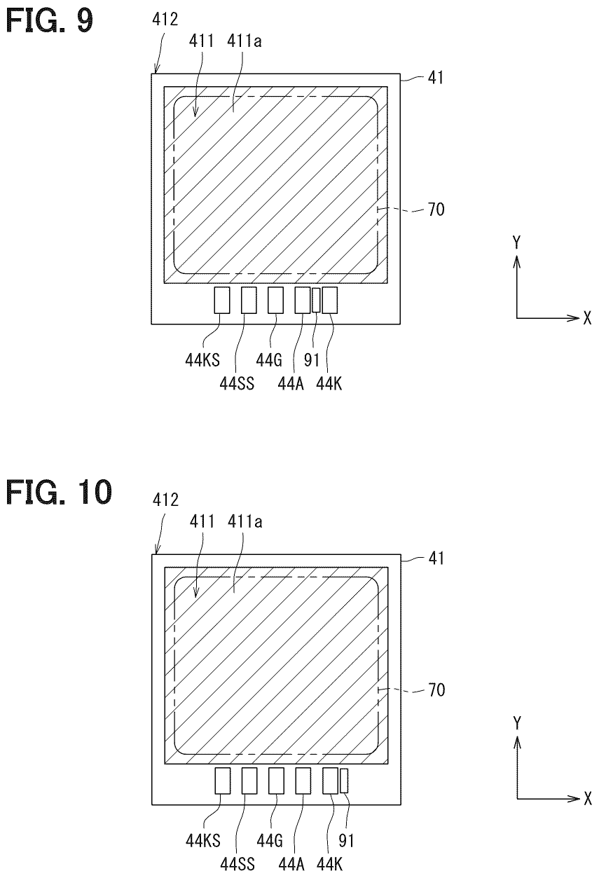

The second to fifth embodiments will be described below. Note that in FIGS. 9 to 12, the illustrations of the voltage withstanding structure 413 and the gate wiring 46 in the semiconductor substrate 41 are omitted. FIG. 9 is a plan view showing a semiconductor substrate 41 according to the second embodiment. In the second embodiment, the active region 411 does not have the right-most active region 411b and the left-most active region 411c, but only has the central active region 411a. This also produces the same effects as the first embodiment. The semiconductor device 20 may not have the current sensor 94.

### Third Embodiment

FIG. 10 is a plan view showing a semiconductor substrate 41 according to the third embodiment. In the third embodiment, the arrangement of the temperature sensor 91 is changed from the configuration of the second embodiment. In the third embodiment, the temperature sensor 91 is provided next to the right side in the X direction, of one of the five pads 44 at the farthest end in the X direction. As an example, the temperature sensor 91 is provided adjacent to the cathode potential detection pad 44K. As another example, the temperature sensor 91 may be provided adjacent to the Kelvin source pad 44KS. This also produces the same effects as the first embodiment.

### Fourth Embodiment

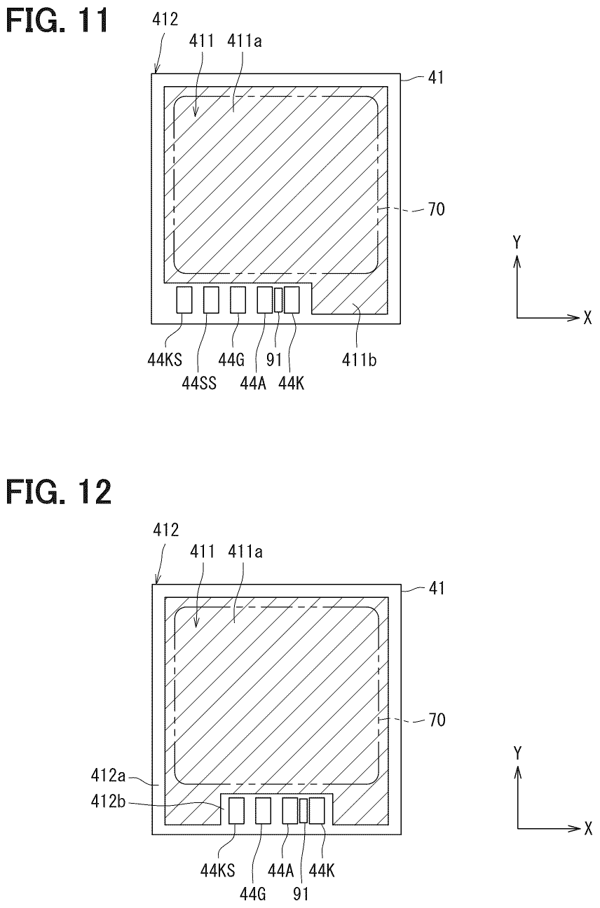

FIG. 11 is a plan view showing a semiconductor substrate 41 according to the fourth embodiment. In FIG. 11, the five pads 44 are provided near the end in the X direction. For example, when the five pads 44 are provided closer to the left end, the active region 411 has the central active region 411a and the right-most active region 411b. The temperature sensor 91 is provided between the two pads 44 or adjacent to the end of the five pads 44 in the X direction. When the temperature sensor 91 is provided between the two pads 44, the area of the right-most active region 411b will not be narrowed. The active region 411 can be expanded.

### Fifth Embodiment

FIG. 12 is a plan view showing a semiconductor substrate 41 according to the fifth embodiment. In the fifth embodiment, there are four pads 44. The number of pads 44 is not limited to five. This also produces the same effects as the first embodiment.

Although the present disclosure has been described in accordance with the embodiments, it is understood that the present disclosure is not limited to such embodiments or structures. The present disclosure includes various modifications and variations within the scope of equivalents. In addition, while various combinations and modes are described in the present disclosure, other combinations and modes including only one element, more elements, or less elements therein are also within the scope and spirit of the present disclosure.

What is claimed is:

1. A semiconductor device comprising:
a semiconductor substrate having an active region in which an element is formed, and an outer peripheral region in which a voltage withstanding structure is formed to surround the active region in a plan view;
a temperature sensor configured to detect a temperature of the semiconductor substrate in the outer peripheral region, wherein the semiconductor device is electrically connected to a control device that detects whether there is an abnormality in a cooling system based on the temperature detected by the temperature sensor, the cooling system cooling the semiconductor substrate; and
a conductive spacer disposed in the active region on one surface of the semiconductor substrate,
the temperature sensor is positioned not to overlap the conductive spacer in a thickness direction, and
the temperature sensor is positioned closer to a center of the semiconductor substrate in an orthogonal direction perpendicular to the thickness direction than the voltage withstanding structure is.

2. The semiconductor device according to claim 1, further comprising a plurality of pads arranged on the one surface in the outer peripheral region, the plurality of pads being electrodes for signal, wherein
the plurality of pads is arranged to be separated from the conductive spacer in a first direction of the orthogonal direction,
the plurality of pads is arranged with a gap in a second direction of the orthogonal direction different from the first direction, and
the temperature sensor is arranged between two of the pads adjacent to each other or located adjacent to an outermost end of the pads in the second direction.

3. The semiconductor device according to claim 2, wherein
the active region has:
a main region arranged adjacent to the plurality of pads in the first direction; and
an extension region smaller in area than the main region in the plan view, wherein
the extension region is connected to an end of the main region adjacent to the pad and is located adjacent to the pad in the second direction.

4. A power control unit comprising:
a semiconductor substrate having an active region in which an element is formed, and an outer peripheral region in which a voltage withstanding structure is formed to surround the active region in a plan view;
a conductive spacer disposed on one side of the semiconductor substrate in the active region;
a temperature sensor configured to detect a temperature of the semiconductor substrate in the outer peripheral region; and
a control device configured to detect whether there is an abnormality in a cooling system that cools the semiconductor substrate based on a detected temperature detected by the temperature sensor, wherein
the temperature sensor is positioned not to overlap the conductive spacer in a thickness direction, and
the temperature sensor is positioned closer to a center of the semiconductor substrate in an orthogonal direction perpendicular to the thickness direction than the voltage withstanding structure is.

5. The power control unit according to claim 4, wherein
the control device includes:
a storage unit to store an assumed temperature of the semiconductor substrate having a predetermined temperature range, which is assumed to be detected by the temperature sensor when a refrigerant normally flows through the cooling system;
a temperature acquisition unit to acquire an actual temperature of the semiconductor substrate detected by the temperature sensor;
a temperature comparison unit to compare the actual temperature and the assumed temperature; and
an abnormality detection unit to detect that there is an abnormality in the cooling system when the actual temperature is out of the predetermined temperature range of the assumed temperature.
